(19) United States
(12) Patent Application Publication
(10) Pub. No.: US 2023/0109316 A1
(43) Pub. Date: Apr. 6, 2023

(54) Under-Display Sensor Lamination

(71) Applicant: Google LLC, Mountain View, CA (US)

(72) Inventors: Ji Hoon Jang, Mountain View, CA (US); Jeffrey Andrew Fisher, Mountain View, CA (US); Andrew McKinley Schroeder, Chicago, IL (US); Avi Pinchas Hecht, Berkeley, CA (US)

(73) Assignee: Google LLC, Mountain View, CA (US)

(21) Appl. No.: 17/937,635

(22) Filed: Oct. 3, 2022

Related U.S. Application Data
(60) Provisional application No. 63/252,096, filed on Oct. 4, 2021.

(51) Int. Cl. H01L 51/52; H01L 27/32; G06V 40/13; G06V 10/147

(52) U.S. Cl. CPC H01L 51/5253; H01L 27/3234; G06V 40/1329; G06V 10/147

(57) ABSTRACT

This document describes systems and techniques directed at under-display sensor lamination. In aspects, an electronic device having a mechanical frame designed with a bucket architecture includes an under-display sensor attached to one or more layers of a display panel stack. Such an implementation enables attachment of the under-display sensor to a protective layer, as opposed to attachment of the sensor directly to a display panel, minimizing the risk of delamination, as well as reducing damage to the display panel if delamination occurs and rework is attempted. Further, such an implementation removes the need for a mid-frame architecture, resulting in a thinner and lighter electronic device.

### BACKGROUND

Electronic devices often include a plurality of electronic components, such as electromechanical transducers (e.g., speakers, microphones), electronic sensors (e.g., ambient light sensors), and electronic visual displays. Further, electronic devices include a housing (e.g., an outer enclosure) which defines at least one internal cavity within which one or more of the plurality of electronic components may be disposed. In additional or alternative applications, one or more of the plurality of electronic components may define portions of, or be integral to, the housing of the electronic device. For example, an electronic visual display can define a portion of a housing of an electronic device.

A mechanical frame (e.g., a chassis) may define, or support, a housing of an electronic device. For example, metallic panels of a mechanical frame may define portions of a housing of an electronic device. In another example, plastic panels can be attached to a mechanical frame and, thereby, define a housing of the electronic device. Mechanical frames can be designed in a variety of configurations, including, for instance, a mid-frame architecture. The mid-frame architecture of a mechanical frame includes a support structure that resides within an internal cavity of an electronic device and physically supports the electronic visual display from a direction normal to an outward-facing surface of the electronic visual display. In some configurations, the support structure extends from a first side of the mechanical frame to a second side of the mechanical frame such that the support structure intersects a center plane of an electronic visual display. In other configurations, the support structure partially extends from a first side of the mechanical frame to a second side of the mechanical frame. In either configuration, the support structure provides a compressive force substantially normal to an outward-facing surface of the electronic visual display at an inward-facing surface, opposite of the outward-facing surface, of the electronic visual display. Additional electronic components, such as the electronic sensors, may also be physically supported by the support structure. For instance, the support structure can physically support an under-display fingerprint sensor.

### SUMMARY

This document describes systems and techniques directed at under-display sensor lamination. In aspects, an electronic device having a mechanical frame designed with a bucket architecture includes an under-display sensor attached to one or more layers of a display panel stack. Such an implementation enables attachment of the under-display sensor to a protective layer, as opposed to attachment of the sensor directly to a display panel, minimizing the risk of delamination, as well as reducing damage to the display panel if delamination occurs and rework is attempted. Further, such an implementation removes the need for a mid-frame architecture, resulting in a thinner and lighter electronic device.

In aspects, an electronic device is disclosed that includes: a housing defining at least one internal cavity; a display panel stack is disclosed that includes: a cover layer, the cover layer being substantially transparent to electromagnetic radiation and integral to the housing of the electronic device; a display panel configured to illuminate, the display panel positioned underneath the cover layer and disposed within the at least one internal cavity; and a protective layer positioned opposite the cover layer with the display panel positioned therebetween, the protective layer including a top face and bottom face, the top face positioned adjacent to the display panel, and wherein the protective layer includes an opening extending from the top face to the bottom face through which electromagnetic radiation emanating from an external environment surrounding the housing propagates, the protective layer is disclosed that includes: a polymer layer configured to protect the display panel from ingress contaminants; and a metallic layer configured to protect the display panel from electromagnetic radiation, the metallic layer positioned underneath the polymer layer and is disclosed that includes the bottom face; and an under-display electronic component positioned within the at least one internal cavity opposite the cover layer and adjacent to the bottom face of the protective layer, the under-display electronic component laminated to the metallic layer such that the under-display electronic component substantially covers the opening.

The details of one or more implementations are set forth in the accompanying Drawings and the following Detailed Description. Other features and advantages will be apparent from the Detailed Description, the Drawings, and the Claims. This Summary is provided to introduce subject matter that is further described in the Detailed Description. Accordingly, a reader should not consider the Summary to describe essential features nor limit the scope of the claimed subject matter.

### BRIEF DESCRIPTION OF THE DRAWINGS

The details of one or more aspects for under-display sensor lamination are described in this document with reference to the following Drawings, in which the use of same numbers in different instances may indicate similar features or components:

FIG. 1 illustrates an example implementation of an example electronic device having a biometric authentication system with an under-display fingerprint sensor and a display panel stack;

FIG. 2 illustrates an example implementation of the example electronic device from FIG. 1;

FIG. 3 illustrates an example implementation of the display from FIG. 2 in more detail;

FIG. 4 illustrates an example implementation of the example electronic device having the display manufactured as a display panel stack;

FIG. 5 illustrates an example implementation of the example display panel;

FIG. 6 illustrates an example implementation of the example electronic device including a biometric authentication system having an example under-display fingerprint sensor configured to capture an image of a fingerprint; and

FIG. 7 illustrates another example implementation of the example electronic device including a biometric authentication system having an example under-display fingerprint sensor configured to capture an image of a fingerprint.

### DETAILED DESCRIPTION

### Overview

This document describes systems and techniques directed at under-display sensor lamination. Many electronic devices (e.g., wireless-network devices, desktops, smartwatches) include a plurality of electronic components, including electromechanical transducers (e.g., speakers, microphones), electronic sensors (e.g., ambient light sensors, image-capture mechanisms), and electronic visual displays, often simply referred to as displays or screens. Electronic device manufacturers fabricate displays in a layered structure (“display panel stack”), containing a cover layer (e.g., cover glass) and a display module having a display panel. The display panel stack further includes one or more of a display panel, a touch layer (e.g., touch sensor panel), a polarizer layer (e.g., polarization filters), an adhesive layer (e.g., glue), and/or a protective layer (e.g., an EMBO layer). The protective layer may include one or more layers, such as a polymer layer (e.g., polyethylene terephthalate (PET) substrate), a metallic layer (e.g., copper layer, stainless steel layer), a foam pad (e.g., to absorb compressive forces during manufacturing or usage), and an adhesive layer.

Protective layers are configured to shield delicate display panels from internal and external mechanical and electromagnetic forces. In addition, these display panels are often expensive to produce, requiring sophisticated manufacturing techniques to intricately design an array of pixel circuits. Each of the pixel circuits may include an organic light-emitting diode (“pixel”) composed of, for example, a red sub-pixel, a green sub-pixel, and/or a blue sub-pixel. Electronic devices can control any of the pixels within a display panel to illuminate at various intensities and wavelengths (e.g., combined wavelengths of the sub-pixels), effective to produce on-screen content (e.g., images). These display panels provide high refresh rates, small display response times, and low power consumption. Such display panels are well-suited for electronic devices, and are further appreciated by users, in large part, because of their display image-quality. Any physical or electrical damage to a display panel can quickly render portions of the display panel inoperable, spoiling user experience. Thus, display panels are handled with great care during manufacturing and are often surrounded by many shielding components, including the protective layer and the cover layer, for protection during manufacturing and/or device usage.

To preserve space on a display-side of an electronic device and, simultaneously, maximize a screen-size while maintaining an overall low profile of the electronic device, a manufacturer may embed electronic sensors under the display. These sensors, often referred to as under-display sensors, can include an under-display fingerprint sensor (UDFPS) (e.g., an ultrasonic UDFPS, an optical UDFPS), an ambient light sensor, an image-capture mechanism (e.g., a camera), and the like. In one example, an ambient light sensor (e.g., a photodetector) is disposed underneath a display panel and is configured to measure an amount of light exterior to the display-side of an electronic device (“ambient light”). In another example, an UDFPS is disposed underneath a display panel and is configured to perform biometric authentication.

An electronic device further includes a housing (e.g., an outer enclosure) which defines at least one internal cavity within which one or more of the plurality of electronic components may be disposed. In at least some implementations, one or more of the plurality of electronic components may define portions of an electronic device housing (e.g., be integral to the electronic device housing). As an example, a display, including the cover layer, can define a portion of an electronic device housing. In another example, an image-capture mechanism, including a glass lens, can define a portion of the electronic device housing.

In implementations, a mechanical frame may define one or more portions of the electronic device housing. As an example, a mechanical frame can include metallic walls that define portions of the electronic device housing. In additional implementations, a mechanical frame may support one or more portions of the electronic device housing. As an example, one or more exterior housing components (e.g., plastic panels) can be attached to the mechanical frame (e.g., a chassis). In so doing, the mechanical frame physically supports the one or more exterior housing components, which define portions of the electronic device housing. In implementations, the mechanical frame and/or the exterior housing components may be composed of crystalline or non-crystalline (e.g., metals, plastics) inorganic solids.

These mechanical frames can be designed in a variety of configurations. In the following disclosure, systems and techniques are described relating to an electronic device having a mechanical frame designed with a bucket architecture. One or more systems and techniques described herein may be applicable to any of a variety of other mechanical frame configurations, however.

In aspects, the mechanical frame designed with a bucket architecture defines an open-sided polyhedron (e.g., an open-sided cylindrical prism). In an example, a mechanical frame designed with a bucket architecture can define an open-sided rounded rectangular prism. In additional implementations, a mechanical frame with a bucket architecture includes housing components that define an open-sided polyhedron. For example, a mechanical frame designed with a bucket architecture may include more than one open side, defining a partial or full skeletal polyhedra (e.g., a polyhedron structure in which vertices and edges are defined by rods and two or more faces are absent). Exterior housing components (e.g., plastic panels) can then be attached to the mechanical frame to define an open-sided polyhedron. In any implementation, the open-sided polyhedron may then be closed through the inclusion of a display (e.g., a cover glass), defining at least one internal cavity.

In the bucket architecture, the mechanical frame may not include a support structure that (i) resides within the internal cavity, (ii) extends from a first wall of the mechanical frame to a second wall of the mechanical frame, and (iii) physically supports the display. Instead, the display may be fully supported by walls of the mechanical frame with the bucket architecture, with or without an adhesive. Through the absence of a support structure, the bucket architecture allows for a more compact design of an electronic device in comparison to, for instance, an electronic device with a mechanical frame having a mid-frame architecture. As an example, a cross sectional thickness of an electronic device with a bucket architecture may be thinner than an electronic device with a mid-frame architecture due to the absence of the support structure. In addition, or alternatively, the absence of a support structure in the bucket architecture may allow for more space within the internal cavity of an electronic device. More space in the internal cavity of an electronic device may be useful for the installation of enlarged batteries with greater charge capacities, the inclusion of additional electronic components, and/or better heat management. Furthermore, manufacturing of an electronic device with a bucket architecture may be more efficient and less expensive (e.g., less material) than other mechanical frame designs.

However, designers and manufacturers of electronic devices who desire to embed sensors underneath displays often utilize mechanical frames designed with a mid-frame architecture, since the support structure included with a mid-frame architecture offers reliable positional support to uphold the under-display sensors. In the absence of a support structure, the positional stability of these under-display sensors is less reliable. A dislocated under-display sensor can not only minimize the effectiveness of the sensor, but it can also damage the delicate display panel (e.g., during a dislocation event). Furthermore, repositioning a dislocated under-display sensor can be challenging and expensive. As a consequence, repositioning an under-display sensor is seldom attempted, often resulting in the abandonment of the electronic device with a dislocated under-display sensor.

To prevent dislocations, designers and manufactures may dispense adhesive on or surrounding the under-display sensors to provide increased positional reliability. However, the application of an adhesive, or an adhesive material (e.g., tape), may involve additional manufacturing steps, increase material usage, and, consequently, result in greater production costs. In addition, dispensing adhesive over or surrounding an under-display sensor can frustrate future reworking and serviceability.

To this end, this document describes systems and techniques directed at under-display sensor lamination. In aspects, an electronic device having a mechanical frame designed with a bucket architecture includes an under-display sensor attached to one or more layers of a display panel stack. Such an implementation enables attachment of the under-display sensor to a protective layer, as opposed to attachment of the sensor directly to a display panel, minimizing the risk of delamination, as well as reducing damage to the display panel if delamination occurs and rework is attempted. Further, such an implementation removes the need for a mid-frame architecture, resulting in a thinner and lighter (e.g., less heavy) electronic device.

The following discussion describes operating environments and techniques that may be employed in the operating environments and example methods. Although techniques using and apparatuses for under-display sensor lamination are described, it is to be understood that the subject of the appended claims is not necessarily limited to the specific features or methods described. Rather, the specific features and methods are disclosed as example implementations and reference is made to the operating environment by way of example only.

### Operating Environment

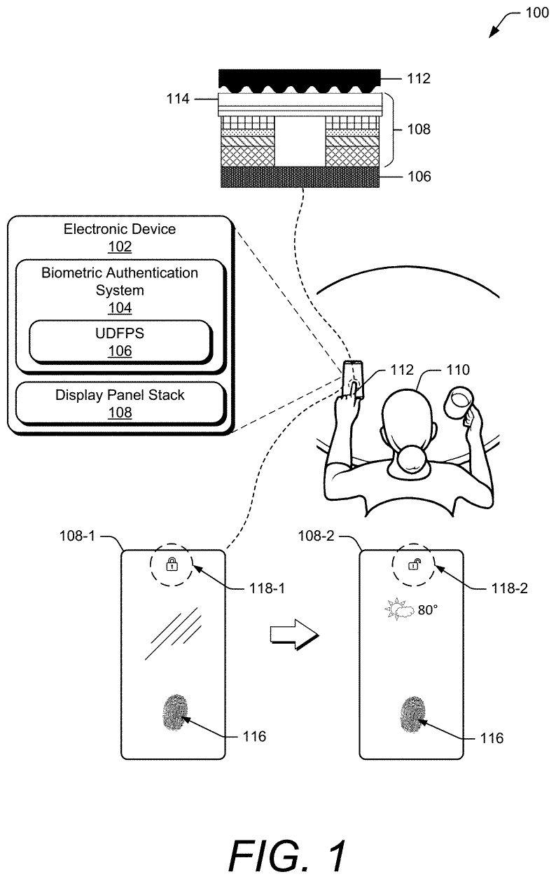

FIG. 1 illustrates an example implementation 100 of an example electronic device 102 having a biometric authentication system 104 with an under-display fingerprint sensor (“UDFPS” 106) and a display panel stack 108. In one example, as illustrated in FIG. 1, a user 110 sitting at a table for morning coffee desires to view daily updates, weather forecasts, messages, news, and so on. To access their electronic device 102 and view daily content, the user 110 places a finger 112 (e.g., a pointer finger) on a cover glass 114 of the display panel stack 108 of her electronic device 102. In response to the user 110 placing their finger 112 on the cover glass 114, the UDFPS 106 may capture an image of a fingerprint 116 associated with the finger 112. The biometric authentication system 104 can then perform biometric analysis of the fingerprint 116 to authenticate the user 110. If the fingerprint 116 of the user 110 is previously enrolled with the biometric authentication system 104, the biometric authentication system 104 may transfer the electronic device 102 from a locked state 118-1 to an unlocked state 118-2.

As illustrated, the display panel stack 108 may contain multiple layers, including a cover glass 114, a display panel, a touch layer (e.g., touch sensor panel), a polarizer layer (e.g., polarization filters), an adhesive layer (e.g., glue), and/or a protective layer (e.g., an EMBO layer). The UDFPS 106 may be positioned underneath one or more of these layers. An opening in the one or more layers may define a visibly unobstructed passageway through which the UDFPS 106 can capture images of the fingerprint 116. In aspects, the UDFPS 106 is laminated to a metallic layer of a protective layer, not a display panel. Such a design minimizes the risk of damage to the display panel during manufacturing and device usage, improves future serviceability if delamination occurs, and enhances positional reliability since the lamination of the UDFPS 106 to the metallic layer can create a more secure bond.

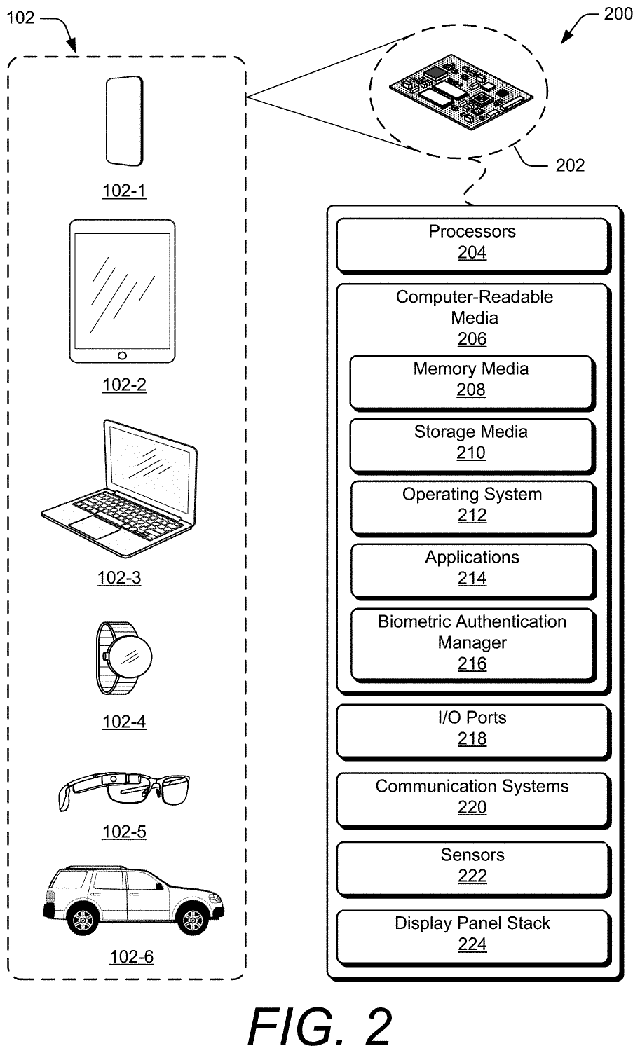

In more detail, consider FIG. 2, which illustrates an example implementation 200 of the example electronic device from FIG. 1. The electronic device 102 is illustrated with a variety of example devices, including consumer electronic devices. As non-limiting examples, the electronic device 102 can be a smartphone 102-1, a tablet device 102-2, a laptop computer 102-3, a computerized watch 102-4, smart glasses 102-5, and an automotive vehicle 102-6. Although not shown, the electronic device 102 may also be implemented as any of a mobile station (e.g., fixed- or mobile-STA), a mobile communication device, a client device, a home automation and control system, an entertainment system, a gaming console, a personal media device, a health monitoring device, a drone, a camera, an Internet home appliance capable of wireless Internet access and browsing, an IoT device, security systems, and the like. Note that the electronic device 102 can be wearable, non-wearable but mobile, or relatively immobile (e.g., desktops, appliances). Note also that the electronic device 102 can be used with, or embedded within, many electronic devices 102 or peripherals, such as in automobiles or as an attachment to a laptop computer. The electronic device 102 may include additional components and interfaces omitted from FIG. 2 for the sake of clarity.

As illustrated, the electronic device 102 includes a printed circuit board assembly 202 (PCBA 202) on which components and interconnects of the electronic device 102 are embodied. In implementations, the PCBA 202 may include multiple printed circuit boards operably coupled together via, for example, electrical wiring. Alternatively, or additionally, components of the electronic device 102 can be embodied on other substrates, such as flexible circuit material or other insulative material. Generally, electrical components and electromechanical components of the electronic device 102 are assembled onto a printed circuit board (PCB) to form the PCBA 202. Various components of the PCBA 202 (e.g., processors and memories) are then programmed and tested to verify the correct function of the PCBA 202. The PCBA 202 is connected to or assembled with other parts of the electronic device 102 into a housing.

As illustrated, the PCBA 202 includes one or more processors 204 and computer-readable media 206. The processors 204 may include any suitable single-core or multi-core processor (e.g., an application processor (AP), a digital-signal-processor (DSP), a central processing unit (CPU), graphics processing unit (GPU)). The computer-readable media 206 may include one or more non-transitory storage devices such as a random access memory, hard drive, solid-state drive (SSD), or any type of media suitable for storing electronic instructions, each coupled with a computer system bus. The term “coupled” may refer to two or more elements that are in direct contact (physically, electrically, magnetically, optically, etc.) or to two or more elements that are not in direct contact with each other, but still cooperate and/or interact with each other.

The computer-readable media 206 includes memory media 208 and storage media 210. An operating system 212, applications 214, and a biometric authentication manager 216 implemented as computer-readable instructions on the computer-readable media 206 can be executed by the processors 204 to provide some or all of the functionalities described herein. For example, the processors 204 may perform specific computational tasks of the operating system 212 directed at controlling the creation and display of on-screen content on a display. In still another example, the processors 204 may execute instructions of the biometric authentication manager 216 directed at controlling an UDFPS (e.g., UDFPS 106) and comparing fingerprints. As described herein, a biometric authentication system (e.g., biometric authentication system 104) includes the biometric authentication manager 216 and the UDFPS.

In additional aspects, various implementations of the biometric authentication manager 216 can include a System-on-a-Chip (SoC), one or more integrated circuits (ICs), a processor with embedded processor instructions or configured to access processor instructions stored in memory, hardware with embedded firmware, a printed circuit board with various hardware components, or any combination thereof. As further described herein, a biometric authentication system may include one or more components of the electronic device 102, as illustrated in FIG. 1, configured to perform biometric authentication. In additional implementations, the biometric authentication system may be implemented as the electronic device 102.

The PCBA 202 may also include input/output (I/O) ports 218 and communication systems 220. The I/O ports 218 allow the electronic device 102 to interact with other devices or users through peripheral devices, conveying any combination of digital signals, analog signals, and radiofrequency (RF) signals. The I/O ports 218 may include any combination of internal or external ports, such as universal serial bus (USB) ports, audio ports, Serial ATA (SATA) ports, PCI-express based ports or card-slots, secure digital input/output (SDIO) slots, and/or other legacy ports. Various peripherals may be operatively coupled with the I/O ports 218, such as human-input devices (HIDs), external computer-readable storage media, or other peripherals.

The communication systems 220 enable communication of device data, such as received data, transmitted data, or other information as described herein, and may provide connectivity to one or more networks and other devices connected therewith. Example communication systems include NFC transceivers, WPAN radios compliant with various IEEE 802.15 (Bluetooth®) standards, WLAN radios compliant with any of the various IEEE 802.11 (WiFi®) standards, WWAN (3GPP-compliant) radios for cellular telephony, wireless metropolitan area network (WMAN) radios compliant with various IEEE 802.16 (WiMAX®) standards, infrared (IR) transceivers compliant with an Infrared Data Association (IrDA) protocol, and wired local area network (LAN) Ethernet transceivers. Device data communicated over communication systems 220 may be packetized or framed depending on a communication protocol or standard by which the electronic device 102 is communicating. The communication systems 220 may include wired interfaces, such as Ethernet or fiber-optic interfaces for communication over a local network, private network, intranet, or the Internet. Alternatively, or additionally, the communication systems 220 may include wireless interfaces that facilitate communication over wireless networks, such as wireless LANs, cellular networks, or WPANs.

Although not shown, the electronic device 102 can also include a system bus, interconnect, crossbar, or data transfer system that couples the various components within the device. A system bus or interconnect can include any one or combination of different bus structures, such as a memory bus or memory controller, a peripheral bus, a universal serial bus, and/or a processor or local bus that utilizes any of a variety of bus architectures.

The PCBA 202 may further include, or be connected to, one or more sensors 222 disposed anywhere on or in the electronic device 102. In some examples, the sensors 222 may be disposed on or in a peripheral input device connected (e.g., wired, wirelessly) to the electronic device 102. The sensors 222 can include any of a variety of sensing components, such as an audio sensor (e.g., a microphone), a touch-input sensor (e.g., a touchscreen), an image-capture device (e.g., a camera, video-camera), proximity sensors (e.g., capacitive sensors), an ambient light sensor (e.g., photodetector), and/or an under-display fingerprint sensor (UDFPS).

The UDFPS can be implemented as an optical UDFPS or as an ultrasonic UDFPS. The UDFPS can be disposed within a housing of the electronic device 102, embedded underneath or within one or more layers of a display panel stack. In implementations, the PCBA 202 can include more than one UDFPS.

The touch-input sensor may be implemented as any of a 5-wire resistive touch panel, a surface capacitive touch panel, a projected capacitive (P-Cap) touch panel, a surface acoustic wave (SAW) touch panel, an infrared (IR) touch panel, a force touch sensor touch panel, and so on. The touch-input sensor may be a transparent substrate.

The electronic device 102 further includes a display panel stack 224 (e.g., display panel stack 108). Although an organic light-emitting diode (OLED) display is described herein, it is provided as an example only. The electronic device 102 may include or utilize any of a variety of displays, including an active-matrix OLED (AMOLED) display, an electroluminescent display (ELD), a microLED display, a liquid crystal display (LCD), a thin film transistor (TFT) LCD, an in-place switching (IPS) LCD, and so forth. The display panel stack 224 may be referred to as, simply, a screen or display.

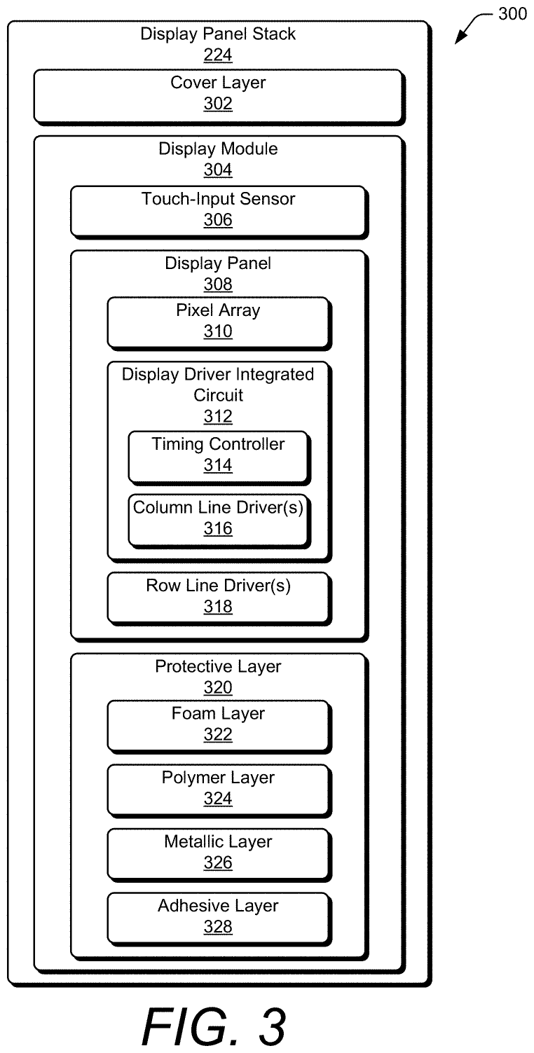

FIG. 3 illustrates an example implementation 300 of the display panel stack 224 from FIG. 2 in more detail. Although FIG. 3 shows various entities and components as part of the display panel stack 224, any of these entities and components may be separate from, but communicatively coupled to, the display panel stack 224.

In FIG. 3, the display panel stack 224 may include a cover layer 302 and a display module 304. The cover layer 302 may be composed of any of a variety of transparent materials including polymers (e.g., plastic, acrylic), glass (e.g., tempered glass), and so forth, forming any three-dimensional shape (e.g., polyhedron), such as a rectangular prism or cylinder. For example, the display panel stack 224 may be implemented as a plastic OLED (POLED) or as a glass OLED (GOLED). During manufacturing, a bottom face of the cover layer 302 may be bonded (e.g., glued) to the display module 304 to protect the display module 304 as well as to serve as a barrier to ingress contaminants (e.g., dust, water).

The display module 304 may include a touch-input sensor 306 and a display panel 308. The display panel 308 may include a pixel array 310 of thousands (or millions) of pixel circuits (e.g., low-temperature polycrystalline oxide (LTPO) pixel circuits), forming any two-dimensional grid (e.g., rectangular grid, circular grid, curved grid). Each pixel circuit may include a light-emitting component, such as one or more light-emitting diodes (LEDs), commonly referred to as a pixel.

The display panel 308 may further include a display driver integrated circuit 312 (DDIC 312). The DDIC 312 may include a timing controller 314 and column line driver(s) 316. The column line driver 316 may include, as a non-limiting example, a data-line driver. The display panel 308 may further include row line drivers 318. The row line drivers 318 may include, as non-limiting examples, gate-line drivers, scan-line drivers, and/or emission-control drivers.

The display panel stack 224 may further include, often integrated within the display module 304, but sometimes altogether separate of the display module 304, a collimator, one or more polarizer layers (e.g., polarization filters), and one or more adhesive layers (e.g., glue). The display module 304 further includes a protective layer 320, commonly referred to as an EMBO layer. The protective layer 320 may include one or more layers, such as a foam layer 322 (e.g., to absorb compressive forces during manufacturing or device usage), a polymer layer 324 (e.g., polyethylene terephthalate (PET) substrate), a metallic layer 326 (e.g., copper layer, stainless steel layer), and an adhesive layer 328. The protective layer 320 may be on the bottom of the display panel stack (e.g., opposite the cover layer 302), providing protection from, for example, moisture, debris, and/or radiation (e.g., electromagnetic radiation, heat radiation).

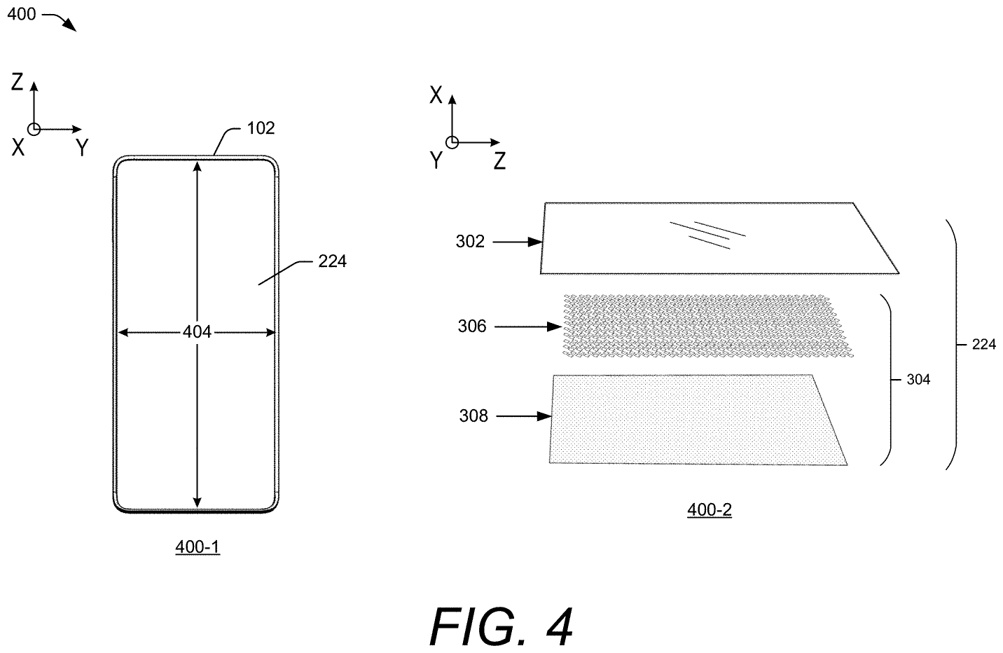

FIG. 4 illustrates an example implementation 400 of the example electronic device 102 (e.g., smartphone 102-1) having the display panel stack 224. As illustrated in detail view 400-1, the electronic device 102 includes at one least layer of the display panel stack 224 (e.g., the cover layer 302) integrated as one or more portions of a housing of the electronic device 102. The display panel stack 224 includes an active area 404 that may be visible and/or accessible to touch by users.

Detail view 400-2 illustrates an exploded view of the display panel stack 224. For clarity in the detail view, some components of the display panel stack 224 are omitted. As illustrated, the display panel stack 224 includes cover layer 302 disposed as a top layer and a display module 304 disposed thereunder. The display module 304 includes the touch-input sensor 306 disposed beneath the cover layer 302 and the display panel 308 disposed beneath the touch-input sensor 306.

In such a configuration, light emitting from the display panel 308 can pass through the touch-input sensor 306 and the cover layer 302 for viewing by users within the active area 404. Further, users can provide user input (e.g., fingerprints) on or above the cover layer 302, within the active area 404, for receipt by one or more sensors 222 (e.g., the UDFPS 106). For example, users can provide user input on the cover layer 302, within the active area 404, for receipt (e.g., detection) by the touch-input sensor 306.

As described herein, user input may include any physical or behavioral characteristic provided (directly or indirectly) by a user from which biometric identifiers (e.g., biological characteristics) can be derived. As non-limiting examples, biometric identifiers can include fingerprints, irises, palms, voice, facial structure, and others.

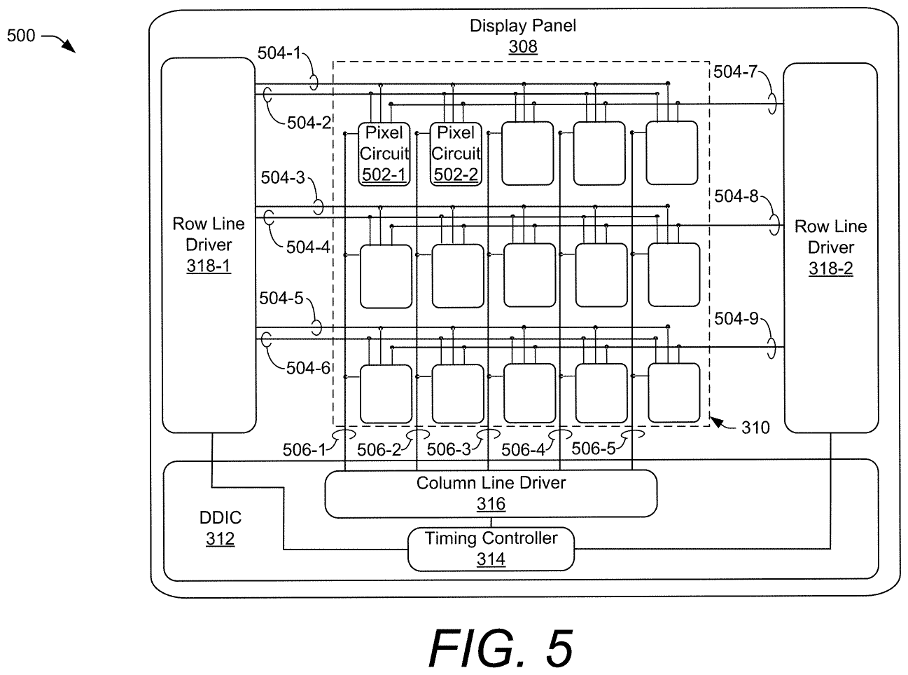

FIG. 5 illustrates an example implementation 500 of an example display panel. In this example, the display panel 308 includes similar components to those described and illustrated with respect to the display panel 308 of FIG. 3, with some additional detail. The display panel 308 can include additional components, not illustrated in FIG. 5. Further, in other implementations, the electronic device 102 may utilize display technology altogether different than the display panel 308.

The display panel 308 includes the pixel array 310 having pixel circuits 502 (e.g., pixel circuit 502-1, pixel circuit 502-2). The pixel array may include a plurality (e.g., hundreds, thousands, millions) of pixel circuits 502, but only fifteen pixel circuits 502 are illustrated in FIG. 5 for sake of clarity and conciseness. The pixel circuits 502 are operably coupled to drivers (e.g., row line drivers 318, column line driver 316). For example, the pixel circuits 502 are operably coupled to row line drivers 318 (e.g., row line driver 318-1, row line driver 318-2) via row lines 504. Further, the pixel circuits 502 are operably coupled to the column line driver 316 via column lines 506. Although two row line drivers 318 are illustrated and only one column line driver 316 is illustrated, the display panel 308 may include a plurality of row line drivers 318 and column line drivers 316. As non-limiting examples, the row line drivers 318 may be implemented as gate line drivers, scan line drivers, and/or emission control drivers. As a non-limiting example, the column line driver 316 may be implemented as a data line driver.

The display panel 308 further includes the DDIC 312 having the column line driver 316 and the timing controller 314. The timing controller 314 can provide interfacing functionality between the processors 204 and the drivers (e.g., column line driver 316, row line drivers 318). The timing controller 314 generally accepts commands and data from the processors 204, generates signals with appropriate voltage, current, timing, and demultiplexing, and passes the signals to the drivers.

The drivers may pass time-variant and amplitude-variant signals (e.g., voltage signals, current signals) to one or more pixel circuits 502 in the pixel array 310 via row lines and/or column lines. For example, a data line driver passes signals containing voltage data to the pixel array 310 to control the luminance of one or more LEDs in the pixel circuits 502. A scan line driver passes a signal to enable or disable one or more LEDs from receiving the data voltage from the data line driver. An emission control driver supplies an emission control signal to the pixel array 310. Together, the drivers control the pixel array 310 to generate light to create an image on the display panel 308.

In implementations, the biometric authentication manager 216 can be configured to instruct (e.g., directly, indirectly via processors 204) the DDIC 312 to alter a brightness at the one or more determined regions within the pixel array 310 of the display panel 308. In some examples, altering a brightness may include increasing a luminance of one or more determined regions, while maintaining a luminance of the display for regions around the determined regions. For example, under the instruction of the biometric authentication manager 216, the DDIC 312 can increase the luminosity of individual LEDs within the one or more regions from a low brightness to a high brightness in response to a user placing a finger near or above the UDFPS 106.

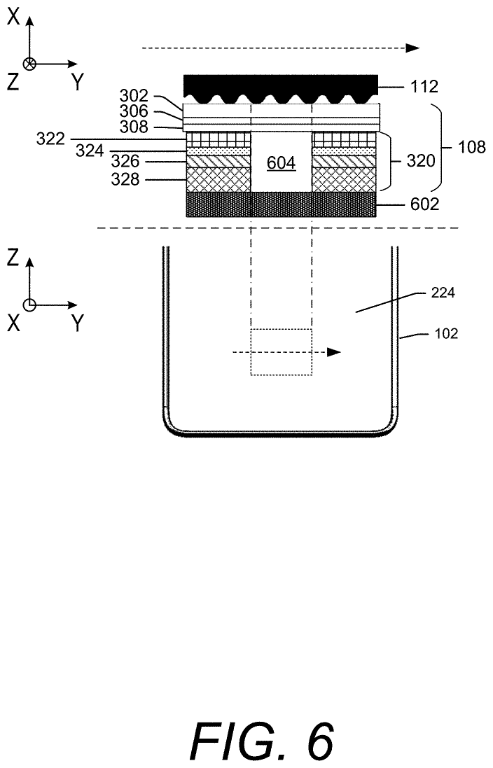

FIG. 6 illustrates an example implementation 600 of the example electronic device 102 including a biometric authentication system having an example UDFPS configured to capture an image of a fingerprint. As illustrated, the electronic device 102 includes an optical UDFPS 602 (e.g., UDFPS 106) disposed underneath the display panel stack 224 within an internal cavity defined by the housing of the electronic device 102. In aspects, the electronic device 102 includes a mechanical frame designed with a bucket architecture.

An opening 604 in the one or more layers of the display panel stack 108 may define a visibly unobstructed passageway through which light can be transmitted such that the UDFPS 106 can capture images of a fingerprint (e.g., fingerprint 116). In at some implementations, the opening 604 may be filled a transparent material (e.g., gel, glue). In implementations, the UDFPS 602 is laminated (e.g., attached, glued, adhered) to a bottom layer of the display panel stack 224 over the opening 604 opposite of the display panel 308. In such a configuration, the optical UDFPS 602 can capture light that is reflected from a finger 112 and transmitted through the cover layer 302, the touch-input sensor 306, the display panel 308, and the opening 604. The biometric authentication manager 216 can then generate (e.g., capture) a frame (“verify print”) containing a visual representation of the finger 112 having a fingerprint (e.g., fingerprint 116). The biometric authentication manager 216 can then compare the verify print to an enrolled print of a previously authenticated user. For example, the biometric authentication manager 216 can compare the verify print to the enrolled print based on whether information (e.g., biometric identifiers, minutia) inferred from the prints match. If the comparison succeeds, then the biometric authentication system can authenticate the user.

Provided that the biometric authentication manager 216 determines that the verify print indicates an authorized user, then the biometric authentication system may permit the user access (e.g., unlock) one or more resources (e.g., a program, an internet-enabled account, a peripheral input device, an operating system) of the electronic device 102.

The one or more layers of the display panel stack 108 through which the visibly unobstructed passageway may be defined includes the protective layer 320. The protective layer includes a foam layer 322, a polymer layer 324, a metallic layer 326, and an adhesive layer 328. In implementations, the adhesive layer 328 may not extend a full length and width of the display panel like the metallic layer 326. Instead, the adhesive layer 328 may surround the opening 604 and possess a width substantially similar to a portion of the UDFPS 602 that expands beyond the area of the opening 604. The protective layer 320 may be on the bottom of the display panel stack (e.g., opposite the cover layer 302), providing protection from, for example, moisture, debris, and/or radiation (e.g., electromagnetic radiation, heat radiation). In implementations, the UDFPS 602 is laminated to the metallic layer 326 via the adhesive layer 328. Such a design simplifies manufacturing techniques, reduces material usage, facilitates potential rework, and allows for a small opening 604 size (e.g., smaller than the UDFPS). Further, in such a design, the display panel 308 is still shielded by the protective layer 320, with the opening 604 adequately sealed by the adhesive layer 328 and UDFPS 602.

In addition to the above descriptions, by covering the opening 604 in the protective layer 320, this configuration avoids the introduction of air gaps surrounding the UDFPS 702. As a result, the opening 604 in the protective layer 320 is minimized, promoting user experience by reducing the potential visibility of the opening 604 through the cover layer 302, touch-input sensor 306, and display panel 308.

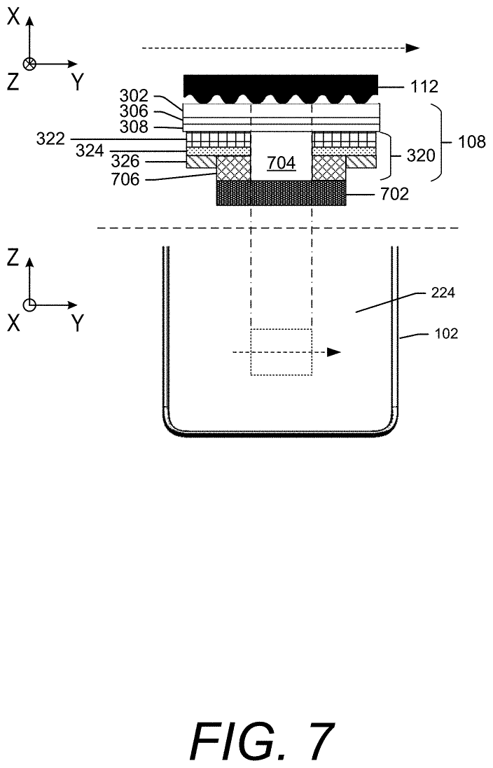

FIG. 7 illustrates another example implementation 700 of the example electronic device 102 including a biometric authentication system having an example UDFPS configured to capture an image of a fingerprint. As illustrated, the electronic device 102 includes an optical UDFPS 702 (e.g., UDFPS 106) disposed underneath the display panel stack 224 within an internal cavity defined by the housing of the electronic device 102. In aspects, the electronic device 102 includes a mechanical frame designed with a bucket architecture.

An opening 704 in the one or more layers of the display panel stack 108 may define a visibly unobstructed passageway through which light can be transmitted such that the UDFPS 106 can capture images of a fingerprint (e.g., fingerprint 116). In at some implementations, the opening 704 may be filled a transparent material (e.g., gel, glue). In implementations, the UDFPS 702 is laminated (e.g., attached, glued, adhered) to a bottom layer of the display panel stack 224 over the opening 704 opposite of the display panel 308. In such a configuration, the optical UDFPS 702 can capture light that is reflected from a finger 112 and transmitted through the cover layer 302, the touch-input sensor 306, the display panel 308, and the opening 704. The biometric authentication manager 216 can then generate (e.g., capture) a frame (“verify print”) containing a visual representation of the finger 112 having a fingerprint (e.g., fingerprint 116). The biometric authentication manager 216 can then compare the verify print to an enrolled print of a previously authenticated user. For example, the biometric authentication manager 216 can compare the verify print to the enrolled print based on whether information (e.g., biometric identifiers, minutia) inferred from the prints match. If the comparison succeeds, then the biometric authentication system can authenticate the user.

Provided that the biometric authentication manager 216 determines that the verify print indicates an authorized user, then the biometric authentication system may permit the user access (e.g., unlock) one or more resources (e.g., a program, an internet-enabled account, a peripheral input device, an operating system) of the electronic device 102.

The one or more layers of the display panel stack 108 through which the visibly unobstructed passageway may be defined includes the protective layer 320. The protective layer includes a foam layer 322, a polymer layer 324, and a metallic layer 326. The protective layer 320 may be on the bottom of the display panel stack (e.g., opposite the cover layer 302), providing protection from, for example, moisture, debris, and/or radiation (e.g., electromagnetic radiation, heat radiation). In implementations, the UDFPS 602 is laminated, via an adhesive 706, to the metallic layer 326 and the polymer layer 324. In such a design configuration, the UDFPS 702 is laminated to two layers of the protective layer 320, which may improve positional reliability by increasing bonding surface area. Further, such a design may decrease a volume of the opening 704 to enhance fingerprint capturing and minimize a cross-sectional thickness of the electronic device 102.

Although techniques have been described herein in reference to, or for use by, an optical UDFPS, at least some of the aforementioned techniques can also be implemented with any of a variety of other electronic components, including an ultrasonic UDFPS, an ambient light sensor, a transceiver (e.g., radar emitter, radar receiver), and so on. Further, although techniques have been described herein in reference to, or for use by, biometric authentication systems, the techniques can be applied to any of a variety of other contexts outside of biometric authentication. Additionally, although techniques have been described herein in reference to, or for use by, a single electronic device (e.g., electronic device 102), the techniques are not limited to being implemented only on one electronic device. Further, in additional implementations, an under-display sensor can be laminated to the foam layer (e.g., foam layer 322).

### EXAMPLES

In the following section, additional examples are provided.

Example 1: An electronic device comprising: a housing defining at least one internal cavity; a display panel stack comprising: a cover layer integral to the housing of the electronic device; a display panel positioned underneath the cover layer and disposed within the at least one internal cavity; and a protective layer positioned opposite the cover layer with the display panel positioned therebetween, the protective layer including a top face and bottom face, the top face positioned adjacent to the display panel, the protective layer including an opening extending from the top face to the bottom face through which electromagnetic radiation emanating from an external environment surrounding the housing propagates, the protective layer comprising: a polymer layer configured to protect the display panel from ingress contaminants; and a metallic layer positioned underneath the polymer layer and comprising the bottom face; and an under-display electronic component positioned within the at least one internal cavity opposite the cover layer and adjacent to the bottom face of the protective layer, the under-display electronic component laminated to the metallic layer such that the under-display electronic component substantially covers the opening.

Example 2: The electronic device of example 1, wherein the under-display electronic component is an under-display fingerprint sensor.

Example 3: The electronic device of example 2, wherein the under-display fingerprint sensor is laminated to the metallic layer in a position that substantially covers the opening in such a way that a sensing face of the under-display fingerprint sensor can sense electromagnetic radiation propagating through the opening from the external environment.

Example 4: The electronic device of example 3, wherein the electromagnetic radiation comprises a reflection of a finger sufficient for capturing an image of a fingerprint by the under-display fingerprint sensor.

Example 5: The electronic device of example 1, wherein the under-display electronic component includes at least one of an ambient light sensor or a transceiver.

Example 6: The electronic device of example 1, wherein the metallic layer comprises at least one of copper or stainless steel.

Example 7: The electronic device of example 1, wherein: the display panel comprises rows of pixel circuits, each of the pixel circuits comprising at least one organic light-emitting diode configured to illuminate, and the electromagnetic radiation emanating from the external environment comprises a reflection of a finger caused by an illumination of the at least one organic light-emitting diode.

Example 8: The electronic device of example 1, wherein the protective layer further comprises: a foam layer positioned above the polymer layer adjacent to the display panel, and wherein the foam layer comprises the top face.

Example 9: The electronic device of example 8, wherein the foam layer is configured to absorb compressive forces.

Example 10: The electronic device of example 1, wherein the electromagnetic radiation comprises visible light and infrared light.

Example 11: The electronic device of example 1, wherein the opening is filled with a transparent material comprising at least one of a gel or an adhesive.

Example 12: The electronic device of example 1, wherein: a first cross-sectional area of the opening in the polymer layer is less than a second cross-sectional area of the opening in the metallic layer; and the under-display electronic component is further laminated to the polymer layer.

Example 13: The electronic device of example 1, wherein the metallic layer is configured to protect the display panel from electromagnetic radiation emanating from one or more electronic components disposed in the internal cavity.

Example 14: The electronic device of example 13, wherein the under-display electronic component substantially covering the opening provides sufficient protection to the display from electromagnetic radiation emanating from one or more electronic components disposed in the internal cavity.

Example 15: The electronic device of example 1, wherein the cover layer is substantially transparent to one or more frequencies of the electromagnetic radiation, the cover layer composed of at least one of plastic or glass.

Example 16: The electronic device of example 1, wherein the electronic device includes a mechanical frame designed with a bucket architecture, the bucket architecture not including a support structure that physically upholds the under-display electronic component.

Example 17: The electronic device of example 1, wherein the electronic device includes a mechanical frame that supports one or more exterior housing components that define the housing.

Example 18: The electronic device of example 1, wherein the protective layer is configured to protect the display from mechanical and electromagnetic forces.

Example 19: The electronic device of example 1, wherein the protective layer comprises at least one adhesive layer.

Example 20: The electronic device of example 1, wherein the electronic device is a smartphone configured to perform biometric authentication.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Although implementations for under-display sensor lamination have been described in language specific to certain features and/or methods, the subject of the appended Claims is not necessarily limited to the specific features or methods described. Rather, the specific features and methods are disclosed as example implementations for under-display sensor lamination.

What is claimed is:

1. An electronic device comprising:
a housing defining at least one internal cavity;
a display panel stack comprising:
a cover layer integral to the housing of the electronic device;
a display panel positioned underneath the cover layer and disposed within the at least one internal cavity; and
a protective layer positioned opposite the cover layer with the display panel positioned therebetween, the protective layer including a top face and bottom face, the top face positioned adjacent to the display panel, the protective layer including an opening extending from the top face to the bottom face through which electromagnetic radiation emanating from an external environment surrounding the housing propagates, the protective layer comprising:
a polymer layer configured to protect the display panel from ingress contaminants; and
a metallic layer positioned underneath the polymer layer and comprising the bottom face; and
an under-display electronic component positioned within the at least one internal cavity opposite the cover layer and adjacent to the bottom face of the protective layer, the under-display electronic component laminated to the metallic layer such that the under-display electronic component substantially covers the opening.

2. The electronic device of claim 1, wherein the under-display electronic component is an under-display fingerprint sensor.

3. The electronic device of claim 2, wherein the under-display fingerprint sensor is laminated to the metallic layer in a position that substantially covers the opening in such a way that a sensing face of the under-display fingerprint sensor can sense electromagnetic radiation propagating through the opening from the external environment.

4. The electronic device of claim 3, wherein the electromagnetic radiation comprises a reflection of a finger sufficient for capturing an image of a fingerprint by the under-display fingerprint sensor.

5. The electronic device of claim 1, wherein the under-display electronic component includes at least one of an ambient light sensor or a transceiver.

6. The electronic device of claim 1, wherein the metallic layer comprises at least one of copper or stainless steel.

7. The electronic device of claim 1, wherein:
the display panel comprises rows of pixel circuits, each of the pixel circuits comprising at least one organic light-emitting diode configured to illuminate, and
the electromagnetic radiation emanating from the external environment comprises a reflection of a finger caused by an illumination of the at least one organic light-emitting diode.

8. The electronic device of claim 1, wherein the protective layer further comprises:
a foam layer positioned above the polymer layer adjacent to the display panel, and wherein the foam layer comprises the top face.

9. The electronic device of claim 8, wherein the foam layer is configured to absorb compressive forces.

10. The electronic device of claim 1, wherein the electromagnetic radiation comprises visible light and infrared light.

11. The electronic device of claim 1, wherein the opening is filled with a transparent material comprising at least one of a gel or an adhesive.

12. The electronic device of claim 1, wherein:
a first cross-sectional area of the opening in the polymer layer is less than a second cross-sectional area of the opening in the metallic layer; and
the under-display electronic component is further laminated to the polymer layer.

13. The electronic device of claim 1, wherein the metallic layer is configured to protect the display panel from electromagnetic radiation emanating from one or more electronic components disposed in the internal cavity.

14. The electronic device of claim 13, wherein the under-display electronic component substantially covering the opening provides sufficient protection to the display from electromagnetic radiation emanating from one or more electronic components disposed in the internal cavity.

15. The electronic device of claim 1, wherein the cover layer is substantially transparent to one or more frequencies of the electromagnetic radiation, the cover layer composed of at least one of plastic or glass.

16. The electronic device of claim 1, wherein the electronic device includes a mechanical frame designed with a bucket architecture, the bucket architecture not including a support structure that physically upholds the under-display electronic component.

17. The electronic device of claim 1, wherein the electronic device includes a mechanical frame that supports one or more exterior housing components that define the housing.

18. The electronic device of claim 1, wherein the protective layer is configured to protect the display from mechanical and electromagnetic forces.

19. The electronic device of claim 1, wherein the protective layer comprises at least one adhesive layer.

20. The electronic device of claim 1, wherein the electronic device is a smartphone configured to perform biometric authentication.
